(19) United States
(12) Patent Application Publication
(10) Pub. No.: US 2025/0175137 A1
(43) Pub. Date: May 29, 2025

(54) CONTROL DEVICE AND CONTROL METHOD

(71) Applicant: DENSO TEN Limited, Kobe (JP)

(72) Inventor: Teruaki HAYASHI, Kobe (JP)

(73) Assignee: DENSO TEN Limited, Kobe (JP)

(21) Appl. No.: 18/596,955

(22) Filed: Mar. 6, 2024

(30) Foreign Application Priority Data
Nov. 24, 2023 (JP) 2023-199241

(51) Int. Cl. H03G 3/30

(52) U.S. Cl. CPC H03G 3/3089

(57) ABSTRACT

A control device includes circuitry configured to: execute control to decrease a gain when a detected temperature of a control target is equal to or higher than a first temperature, and then increase the gain when the detected temperature becomes lower than the first temperature, the gain when outputting an electric signal being adjustable; and cause a temporal change of the gain to be smaller when increasing the gain than when decreasing the gain.

### CROSS-REFERENCE RELATED APPLICATIONS

This application is based on and claims priority under 35 USC 119 from Japanese Patent Application No. 2023-199241 filed on Nov. 24, 2023, the contents of which are incorporated herein by reference.

### TECHNICAL FIELD

The present disclosure relates to a control device and a control method.

### BACKGROUND

Related art discloses a high temperature protection circuit, whose purpose is to keep rise of a temperature smooth upon detecting that a temperature of a device reaches a prescribed temperature (for example, see Japanese Patent Application Laid-Open Publication No. 2017-163240). Upon receiving a high temperature warning signal, the high temperature protection circuit lowers a prescribed threshold level for compressing a dynamic range of an audio signal and compresses a magnitude range of volume of the audio signal.

However, when the high temperature warning signal is received, reliability of the high temperature protection circuit may not be sufficient by simply compressing the magnitude range of the volume. For example, a temperature of a device to be controlled or monitored may vary in a complicated manner depending on an output of the device exemplified by the audio signal.

Accordingly, a control device for the device, which is exemplified by the high temperature protection circuit, requires stable and reliable control not only when the high temperature warning signal is generated but also when the high temperature warning signal is eliminated.

An object of an embodiment of the disclosure is to quickly, stably and reliably control a temperature of a control target such as a device or a circuit.

### SUMMARY

An aspect of an embodiment of the disclosure is exemplified by a control device. The control device includes circuitry configured to: execute control to decrease a gain when a detected temperature of a control target is equal to or higher than a first temperature, and then increase the gain when the detected temperature becomes lower than the first temperature, the gain when outputting an electric signal being adjustable; and cause a temporal change of the gain to be smaller when increasing the gain than when decreasing the gain.

Since the temporal change of the gain is made smaller when increasing the gain than when decreasing the gain, the control device can make it less likely that the detected temperature of the control target easily returns to a state of being equal to or higher than the first temperature even when the temperature of the control target rapidly rises by increasing the gain. Accordingly, the control device can stably and reliably control the temperature of the control target such as a device or a circuit.

### BRIEF DESCRIPTION OF DRAWINGS

Exemplary embodiments of the present disclosure will be described in detail based on the following figures, wherein:

FIG. 1 is a system configuration diagram showing a control system according to a first embodiment;

FIG. 2 is a timing chart showing control of an amplifier IC by a microcomputer;

FIG. 3 shows a control process executed by the microcomputer;

FIG. 4 shows details of warning monitoring;

FIG. 5 shows an example of the control system;

FIG. 6 shows a configuration of a control system according to a second embodiment; and

FIG. 7 shows a configuration of a control system according to a third embodiment.

### DESCRIPTION OF EMBODIMENTS

### First Embodiment (Configuration)

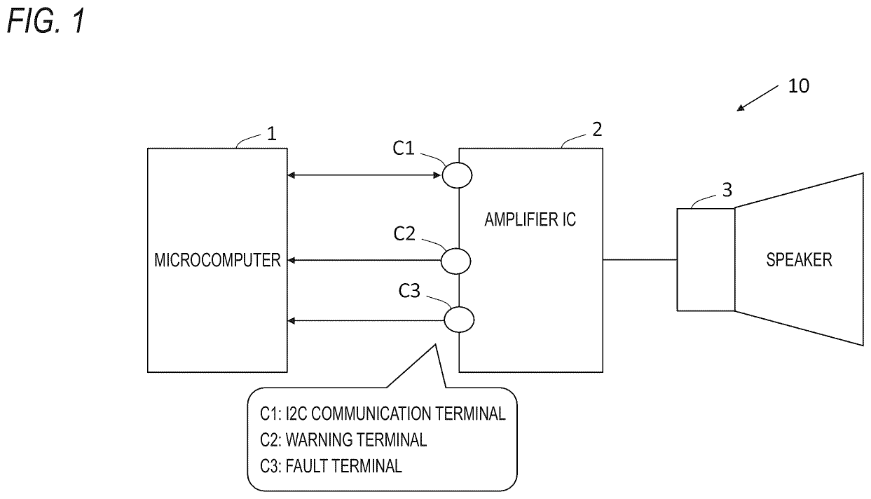

A control device and a control method according to a first embodiment will be described with reference to FIGS. 1 to 4. FIG. 1 is a system configuration diagram showing a control system 10 according to the first embodiment. The control system 10 includes a microcomputer 1, an amplifier integrated circuit (IC) 2, and a speaker 3. In the control system 10, the microcomputer 1 operates as the control device and controls the amplifier IC 2 which is a control target. The amplifier IC 2, which is also referred to as an audio amplifier, receives temperature control by the microcomputer 1, and drives the speaker 3 to output sound.

The microcomputer 1 is also referred to as a microcontroller or a computer. The microcomputer 1 includes, for example, a CPU, a memory, and an interface. The CPU executes a computer program loaded in a memory in an executable manner, and provides functions as a control device. The CPU is also referred to as a processor. The CPU is not limited to a single processor, and may have a multiprocessor configuration. The CPU may be a single processor connected by a single socket and may have a multi-core configuration. At least a part of processes of the microcomputer 1 may be provided by a dedicated processor such as a digital signal processor (DSP), a graphic processing unit (GPU), a numerical data processor, a vector processor, or an image processing processor, an application specific integrated circuit (ASIC), or the like. At least a part of the microcomputer 1 may be a dedicated large scale integration (LSI) such as a field-programmable gate array (FPGA), or another digital circuit. At least a part of the microcomputer 1 may include an analog circuit.

The memory stores computer programs executed by the CPU, data processed by the CPU, and the like. The memory is a dynamic random access memory (DRAM), a static random access memory (SRAM), a read only memory (ROM), or the like.

As described above, the microcomputer 1 includes the interface and inputs a signal from an external device such as the amplifier IC 2 to the CPU. The microcomputer 1 outputs an output signal to the external device such as the amplifier IC 2 via the interface.

The amplifier IC 2 amplifies, for example, an input signal and outputs the amplified signal to an output-side device such as the speaker 3. The input signal and the output signal of the amplifier IC 2 are, for example, sound or audio signals, and are referred to as audio signals. The audio signals are amplified by the amplifier IC 2 to drive the speaker 3.

The amplifier IC 2 includes a temperature sensor therein, which measures a temperature of the amplifier IC 2. A type, a method, and a configuration of the temperature sensor are not limited. The temperature sensor may include, for example, a thermistor, or a thermoresistor. The amplifier IC 2 further includes a first control circuit that outputs an alarm signal to a terminal C2 when the temperature measured by the temperature sensor reaches a reference temperature (also referred to as a first temperature) defined by a standard or a specification.

The first control circuit outputs a HI signal in, for example, a normal state in which the temperature measured by the temperature sensor does not reach the reference temperature. The first control circuit outputs a LO signal as the alarm signal when the temperature measured by the temperature sensor reaches the reference temperature. The alarm signal is not limited to the LO signal. That is, the first control circuit may output the LO signal to the terminal C2 in the normal state, and may output the HI signal to the terminal C2 as the alarm signal when the temperature measured by the temperature sensor reaches the reference temperature.

The amplifier IC 2 further includes a second control circuit that outputs a fault signal when the temperature measured by the temperature sensor reaches a limit temperature (also referred to as a second temperature) defined by a standard or a specification. The limit temperature is higher than the reference temperature. When the temperature of the amplifier IC 2 reaches the limit temperature, the amplifier IC 2 stops an amplification function. Operation of the second control circuit is the same as that of the first control circuit, and thus a description thereof is omitted. That is, the first control circuit and the second control circuit are different regarding whether the temperature compared with the measured temperature is the reference temperature or the limit temperature, and are the same regarding operation of the circuit. The first control circuit and the second control circuit may be the same circuit.

In the present embodiment, the amplifier IC 2 includes terminals C1 to C3 to transmit and receive signals to and from the interface of the microcomputer 1 and input signals to the interface of the microcomputer 1. The terminal C1 executes serial communication with the microcomputer 1 by an inter-integrated circuit (I2C). The microcomputer 1 reads values of various registers of the amplifier IC 2 through the terminal C1 by I2C communication. The microcomputer 1 sets values, for example, commands or control parameters, in various registers of the amplifier IC 2 through the terminal C1 by I2C communication. For example, the microcomputer 1 sets a gain of the amplifier IC 2 by I2C communication. A communication method between the microcomputer 1 and the amplifier IC 2 is not limited to I2C communication. Communication between the microcomputer 1 and the amplifier IC 2 may be executed by another communication method such as serial peripheral interface (SPI) communication.

The terminal C2 is referred to as a warning terminal. When the temperature of the amplifier IC 2 reaches the reference temperature (the first temperature) while the amplifier IC 2 is amplifying an audio signal, the amplifier IC 2 outputs an alarm signal to the terminal C2 by the first control circuit.

The terminal C3 is referred to as a fault terminal. When the temperature of the amplifier IC 2 reaches the limit temperature (the second temperature) while the amplifier IC 2 is amplifying an audio signal, the amplifier IC 2 outputs a fault signal by the second control circuit to notify of a fault to the terminal C3.

### Process Example

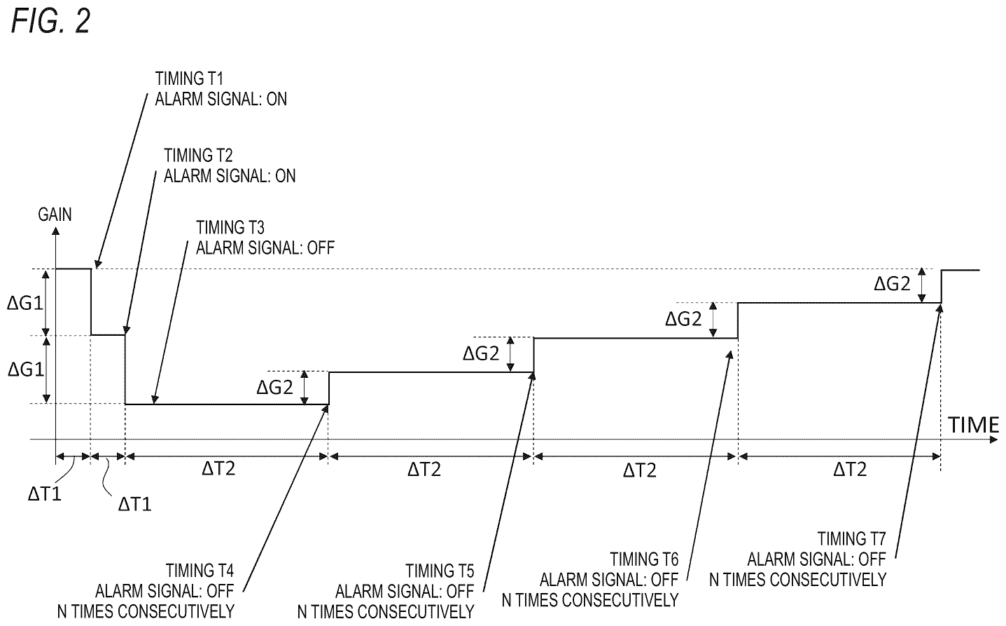

FIG. 2 is a timing chart showing control of the amplifier IC 2 by the microcomputer 1. In FIG. 2, a horizontal axis represents time, and a vertical axis represents an instruction value (also referred to as a control amount) of the gain of the amplifier IC 2. In FIG. 2, it can be understood that the vertical axis represents the gain of the amplifier IC 2. In this case, FIG. 2 may also be said to be a timing chart showing operation of the amplifier IC 2.

In this example, an alarm signal is input to the microcomputer 1 from the terminal C2 of the amplifier IC 2 at, for example, a timing T1 on the time axis (TIME). In the present embodiment, for example, when the terminal C2 is LO, the alarm signal is turned on (also referred to as asserted), and the microcomputer 1 detects an effective alarm signal. When the temperature measured by the temperature sensor is equal to or higher than a reference value, the amplifier IC 2 keeps the alarm signal on.

Upon detecting the alarm signal, the microcomputer 1 writes an instruction (control amount) to decrease the gain by ΔG1 in a register of the amplifier IC 2. Then, the amplifier IC 2 decreases the gain of the amplifier by ΔG1. The instruction (control amount) written in the amplifier IC 2 by the microcomputer 1 may be a difference value (ΔG1) indicating a change amount, or a gain value (G1−ΔG1) itself. Here, G1 is the gain of the amplifier IC 2 before the alarm signal is turned on. The microcomputer 1 detects a state of the amplifier IC 2 at a cycle (for example, ΔT1) determined in advance according to a specification of the system or at a cycle determined in design, and repeats setting the control amount for the amplifier IC 2. The cycle is a cycle in which the microcomputer 1 may control the amplifier IC 2, and is also a cycle for detecting the state of the amplifier IC 2, and is thus also referred to as a monitoring cycle.

In the example of FIG. 2, the alarm signal from the terminal C2 of the amplifier IC2 is kept on even at a timing T2 at which next control is executed. Then, the microcomputer 1 writes an instruction to further decrease the gain by ΔG1 to a register of the amplifier IC 2. According to such control, when the temperature measured by the temperature sensor is lower than the reference value, the amplifier IC 2 turns off (also referred to as negates) the alarm signal.

In this example, the alarm signal from the terminal C2 of the amplifier IC2 is turned off at a timing T3. In the present embodiment, the microcomputer 1 does not change the gain of the amplifier IC 2 by turning off the alarm signal only once. In FIG. 2, the gain immediately before the timing T3 is kept as it is. Further, in this example, the microcomputer 1 consecutively detects N times that the alarm signal is kept off at a timing T4. For this reason, a period ΔT2 from the timing T2 at which the alarm signal is detected to be on for a last time to the timing T4 at which an N-th off is detected is ΔT2=ΔT1*N. Here, * represents multiplication.

In FIG. 2, in each of the periods ΔT2 from the timing T4 to T5, from the timing T5 to T6, and from the timing T6 to T7, the alarm signal from the terminal C2 of the amplifier IC2 is consecutively kept off N times. In this way, upon detecting that the alarm signal is consecutively kept off N times during ΔT2, the microcomputer 1 writes an instruction (control amount) to increase the gain by ΔG2 to a register of the amplifier IC 2 by I2C communication through the terminal C1. Then, the amplifier IC 2 increases the gain of the amplifier by ΔG2. The instruction (control amount) written in the amplifier IC 2 by the microcomputer 1 may be an increase amount (ΔG2, a value indicating a difference value) or a gain value (G2+ΔG2) itself. Here, G2 is the gain of the amplifier IC2 before the gain is increased by ΔG2. In the present embodiment, ΔG1, which is a decrease amount of the gain, is larger than ΔG2, which is an increase amount.

As described above, the microcomputer 1 checks the alarm signal at the terminal C2 of the amplifier IC 2 before a timing to execute control. That is, the microcomputer 1 checks the alarm signal at the terminal C2 of the amplifier IC 2 for each cycle ΔT1 which is a monitoring cycle. Upon checking that the alarm signal is off, the microcomputer 1 does not immediately increase the gain of the amplifier IC 2. That is, the microcomputer 1 increases the gain of the amplifier IC 2 upon consecutively detecting that the alarm signal is kept off in N monitoring cycles. The microcomputer 1 executes the same check when increasing the gain at any of the timings T4, T5, T6, and T7.

N is an integer of 2 or more, and is determined by characteristics, specifications, configurations, and the like of the amplifier IC 2. For example, when temperature characteristics of the amplifier IC2 are stable, or when the amplifier IC2 is relatively resistant to heat, N can be a relatively small number close to 1. Whether the temperature characteristics of the amplifier IC 2 are relatively resistant to heat can be determined from, for example, a value in the specifications of the amplifier IC 2. In addition, a case in which a heat radiation component such as a heat radiation plate or a heat sink is installed with sufficient guarantee performance in the amplifier IC 2 is exemplified as a case in which the temperature characteristics of the amplifier IC 2 are stable. On the other hand, when the temperature characteristics of the amplifier IC 2 are not stable, or when the amplifier IC 2 is relatively weak to heat, N is desired to be a relatively large number away from 1.

In this way, when increasing the gain of the amplifier IC 2, the microcomputer 1 can stably control the gain of the amplifier IC 2 by checking that the alarm signal is off a plurality of times. On the other hand, when decreasing the gain of the amplifier IC 2, the microcomputer 1 immediately decreases the gain by one detection of on of the alarm signal. This is because quick control is desirable for protecting the amplifier IC 2 when the alarm signal is on. However, when increasing the gain of the amplifier IC 2, stable control is more desirable than protecting the amplifier IC 2. The microcomputer 1 implements both quick protection and stable control of the amplifier IC 2 by changing the number of times for checking presence or absence of the alarm signal in a situation of gain increase and a situation of gain decrease. The microcomputer 1 further implements both quick protection and stable control of the amplifier IC 2 by making ΔG1, which is a decrease amount of the gain, larger than ΔG2, which is an increase amount.

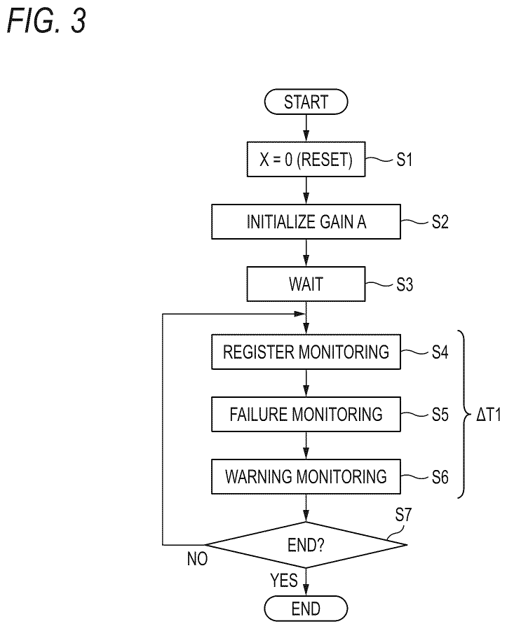

FIG. 3 shows a control process executed by the microcomputer 1. The process starts, for example, when a power supply of an audio apparatus equipped with the control system 10 is turned on. For example, the process starts when an accessory power supply of a vehicle equipped with the control system 10 is turned on.

In the process, the microcomputer 1 resets a variable X to 0 (S1). The variable X is a counter that counts the number of times N for consecutively detecting off of the alarm signal. The microcomputer 1 sets the gain (A) of the amplifier IC 2 to an initial value (S2). In the following process, the current gain is A. By setting the initial value of the gain, the microcomputer 1 can initialize the amplifier IC 2 to the same state, for example, each time the power supply of the audio apparatus is turned on or each time the accessory power supply of the vehicle is turned on. In the present embodiment, the gain (A) is not a gain that can be set by a user, but a gain that is controlled inside the amplifier IC 2. For example, an amplitude (volume) of the output signal to the speaker 3 of the audio apparatus is defined by multiplying the gain set by the user by the gain controlled inside the amplifier IC 2. The gain controlled by the microcomputer 1 is not limited to the gain controlled inside the amplifier IC 2, and may be a gain that can be operated by the user. The gain that can be operated by the user is, for example, a volume instruction value set by a knob, a scale, or the like.

Next, the microcomputer 1 waits for a period defined by the specifications of the system to elapse (S3). The process of S3 is referred to as WAIT. With WAIT, the microcomputer 1 can stabilize the control system 10 after the control system 10 is powered on.

Next, the microcomputer 1 executes register monitoring (S4). The register monitoring is a process of reading a value of a register inside the amplifier IC 2 by I2C communication. The microcomputer 1 can execute a fail-safe other than processes performed in S5 and S6 described below by register monitoring.

Next, the microcomputer 1 executes fault monitoring (S5). The fault monitoring is a process of checking whether the fault signal is on at the terminal C3 of the amplifier IC 2. When the fault signal is on, the microcomputer 1 forcibly and abnormally ends the process. In the present embodiment, a description of forcibly and abnormally ending the process is omitted.

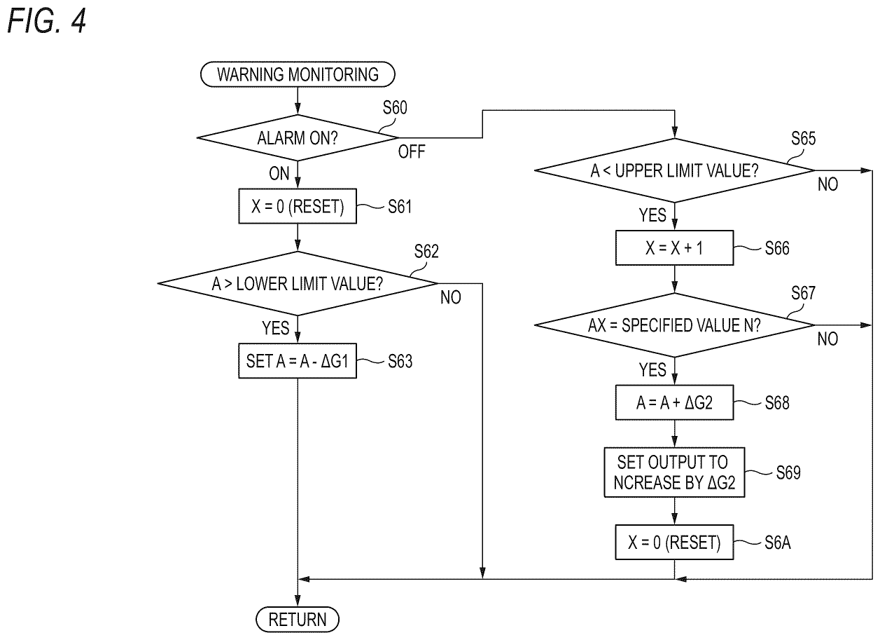

Next, the microcomputer 1 executes warning monitoring (S6). The warning monitoring is a process of checking whether the alarm signal is on at the terminal C2 of the amplifier IC 2 and controlling the amplifier IC 2 according to a check result. Details of the warning monitoring will be separately described with reference to FIG. 4. As already described with reference to FIG. 2, the processes from S4 to S6 are repeatedly executed at the cycle ΔT1 (NO in S7).

Here, a case of NO in S7 is a case in which the control system 10 including the microcomputer 1 is executing normal operation. That is, the microcomputer 1 detects the state of the amplifier IC 2 at each monitoring cycle (each ΔT1) for monitoring the amplifier IC 2 which is a control target. On the other hand, for example, when the power supply of the audio apparatus equipped with the control system 10 is turned off or the accessory power supply of the vehicle equipped with the control system 10 is turned off (YES in S7), the microcomputer 1 ends the process.

FIG. 4 shows details of the warning monitoring (S6 in FIG. 3). In this process, the microcomputer 1 determines whether the alarm signal is on at the terminal C2 of the amplifier IC 2 (S60). When the alarm signal is on, the microcomputer 1 resets the variable X to be 0 (S61). The variable X is reset in S1 of FIG. 3, and is also reset in the process of FIG. 4. Since the process of FIG. 4 is repeatedly executed at the cycle ΔT1, when the alarm signal is on, the variable X is reset in preparation for a process after a next gain decrease.

Next, the microcomputer 1 determines whether the current gain (A) of the amplifier IC 2 exceeds a lower limit value of the gain defined by the specifications of the amplifier IC 2 (S62). When the current gain (A) is equal to or less than the lower limit value of the gain (NO in S62), the microcomputer 1 returns from the warning monitoring to the process of FIG. 3 (RETURN). When the current gain (A) is equal to or less than the lower limit value of the gain, the microcomputer 1 cannot cope with on of the alarm signal, that is, a temperature rise of the amplifier IC 2. Accordingly, the microcomputer 1 returns the process to FIG. 3 and executes an abnormality process by fault monitoring in S5.

On the other hand, when the current gain (A) exceeds the lower limit value of the gain (YES in S62), the microcomputer 1 decreases the gain (A) by ΔG1, sets A=A−ΔG1, and writes the gain (A) in a register of the amplifier IC 2 (S63). At this time, the microcomputer 1 may issue a warning (display, sound, or the like). That is, the warning is not necessary and may be omitted. A type of the warning is not limited. For example, the microcomputer 1 may cause a light emitting diode (LED) indicating a warning to emit light. The microcomputer 1 may output a sound including a warning message or a warning sound from the speaker 3 before the process of decreasing the gain (A) in S63. When a display device is connected to the microcomputer 1, the microcomputer 1 may display an image including a warning message on the display device. When the microcomputer 1 is mounted on a vehicle, the microcomputer 1 may display an image including a warning message on an in-vehicle information processing device including a display device, for example, a car navigation device. Then, the microcomputer 1 returns from the warning monitoring to the process of FIG. 3 (RETURN).

Upon determining in S60 that the alarm signal is off, the microcomputer 1 determines whether the current gain (A) of the amplifier IC 2 is less than an upper limit value of the gain defined by the specifications of the amplifier IC 2 (S65). When the current gain (A) is equal to or greater than the upper limit value of the gain (NO in S65), the microcomputer 1 returns from the warning monitoring to the process of FIG. 3 (RETURN). When the current gain (A) is equal to or greater than the upper limit value of the gain, the microcomputer 1 cannot increase the gain further. Then, the microcomputer 1 returns the process to FIG. 3. That is, the current gain (A) is kept as it is.

On the other hand, when the current gain (A) does not reach the upper limit value of the gain (YES in S65), the microcomputer 1 increases the variable X by 1 (S66). Then, the microcomputer 1 determines whether the variable X reaches a specified value N (S67). When the variable X does not reach the specified value N (NO in S67), the microcomputer 1 returns from the warning monitoring to the process of FIG. 3 (RETURN). The microcomputer 1 performs RETURN in order to check whether the alarm signal is consecutively off in a plurality of (N) monitoring cycles (ΔT1) until the variable X reaches the specified value N. Accordingly, when the cycle ΔT1 further elapses and the alarm signal is kept off even in a next warning monitoring, the determination of S67 is executed again.

On the other hand, when the variable X reaches the specified value N (YES in S67), the microcomputer 1 increases the current gain (A) by ΔG2 (S68), sets A=A+ΔG2, and writes the gain A in a register of the amplifier IC 2 (S69). That is, the microcomputer 1 sets an output of the amplifier IC 2 to increase. Then, the microcomputer 1 resets the variable X to 0 (S6A). The microcomputer 1 executes the control to increase the current gain (A), and checks whether the alarm signal is consecutively off in a plurality of (N) monitoring cycles (ΔT1) until the variable X reaches the specified value N from 0 again until a next gain increase. For this reason, the microcomputer 1 resets the variable X. Then, the microcomputer 1 returns from the warning monitoring to the process of FIG. 3 (RETURN).

### Examples

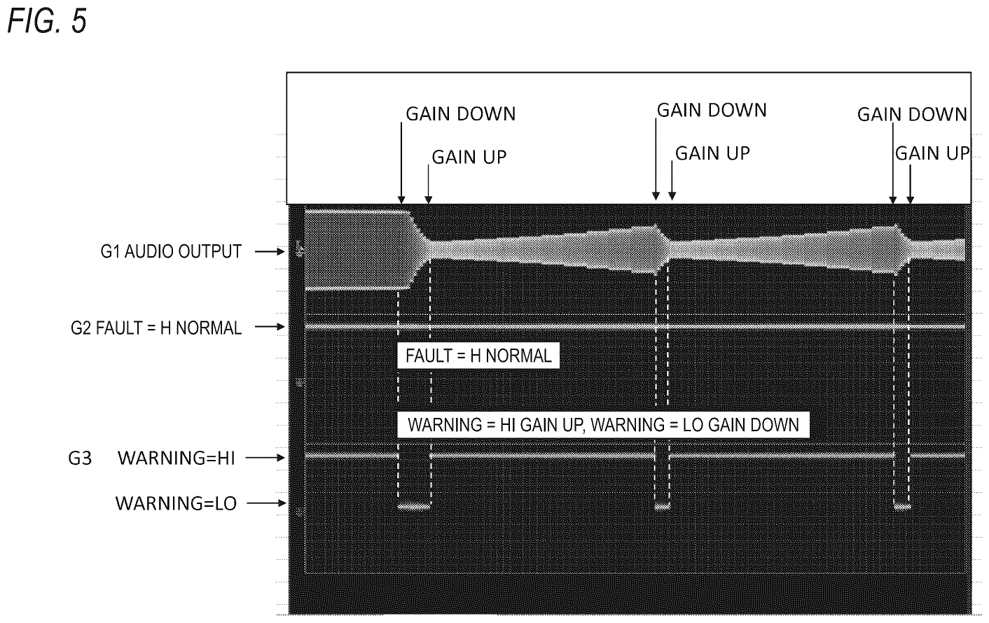

FIG. 5 shows an example of the present control system 10. FIG. 5 shows waveforms obtained by observing an audio output signal of the amplifier IC 2 to the speaker 3, a fault signal (FAULT) of the terminal C3, and an alarm signal (WARNING) of the terminal C2 by an oscilloscope (also referred to as an oscillograph). In FIG. 5, a horizontal axis represents time. In FIG. 5, three signals are displayed in an upper part, a middle part, and a lower part. The upper part shows a waveform G1 of the audio output signal of the amplifier IC 2 to the speaker 3. In the present embodiment, a sine wave is used as the audio output signal. The middle part shows a waveform G2 of the fault signal (FAULT) of the terminal C3. The lower part shows a waveform G3 of the alarm signal (WARNING) of the terminal C2. In FIG. 5, it can be seen that the gain decreases (GAIN DOWN) and the audio output signal decreases in a stepwise manner in accordance with a section of alarm signal on (WARNING=LO).

In FIG. 5, it can be seen that the gain increases (GAIN UP) and the audio output signal increases in a stepwise manner in accordance with a section of alarm signal off (WARNING HI) next to the section of the alarm signal on (WARNING LO). A temporal change rate (a rate of change of an output decrease) of the audio output signal when the gain decreases is steeper than a temporal change (a rate of change of an output increase) of the audio output signal when the gain increases. That is, when the gain increases, it can be seen that the microcomputer 1 increases the gain by ΔG2 each time the alarm signal off (WARNING HI) is detected consecutively N (the specified value) times. As already described in FIG. 2, ΔG1 is larger than ΔG2.

### Effects of First Embodiment

As described above, the amplifier IC 2 can be regarded as an example of a control target whose gain can be adjusted when outputting an audio output signal which is an electric signal. The amplifier IC 2 turns on an alarm signal and outputs the alarm signal to the terminal C2 when the temperature detected by the temperature sensor is equal to or higher than the reference temperature (the first temperature). When the alarm signal is on at the terminal C2, the microcomputer 1, which is an example of the control device, decreases the current gain (A) of the amplifier IC 2 to (A=A−ΔG1). Here, the decrease amount ΔG1 when decreasing the gain is larger than the increase amount ΔG2 when increasing the gain. Thereafter, when the detected temperature is below the reference temperature (the first temperature), the amplifier IC2 turns off the alarm signal and outputs the alarm signal to the terminal C2. Then, before increasing the current gain (A) of the amplifier IC 2 to (A=A+ΔG2), the microcomputer 1 checks that the detected temperature is below the reference temperature (the first temperature) by monitoring N times. As a result, in the present embodiment, the microcomputer 1 makes the temporal change (as an example, rate of change) of the gain larger when decreasing the gain than when increasing the gain. That is, when the temperature of the amplifier IC 2 is equal to or higher than the reference temperature (the first temperature), the microcomputer 1 can execute control to quickly decrease the temperature of the amplifier IC 2. In this case, it can also be said that the microcomputer 1 can implement stable control by making the temporal change of the gain smaller when increasing the gain than when decreasing the gain.

When the temperature detected by the temperature sensor reaches the limit temperature (the second temperature) higher than the reference temperature (the first temperature), the amplifier IC 2 turns on the fault signal and outputs the fault signal to the terminal C3. When the fault signal is on at the terminal C3, the microcomputer 1 executes the abnormality process. That is, when the temperature of the amplifier IC 2 reaches the limit temperature, the microcomputer 1 stops a normal process and immediately responds to an abnormality. Accordingly, the microcomputer 1 can execute a next best process in an abnormal state of the amplifier IC 2.

The microcomputer 1 outputs a warning (display, sound) when the detected temperature of the amplifier IC 2 is equal to or higher than the reference temperature (the first temperature). Accordingly, the microcomputer 1 can notify a user of the audio apparatus including the control system 10, the vehicle equipped with the control system 10 or the like that the temperature of the amplifier IC 2 is equal to or higher than the reference temperature (the first temperature).

In addition, the microcomputer 1 detects a state of the amplifier IC 2, for example, the alarm signal for each monitoring cycle (for example, the cycle ΔT1) for monitoring the amplifier IC 2 which is an example of a control target. When the microcomputer 1 detects that the detected temperature is below the reference temperature (the first temperature) in a plurality of consecutive monitoring cycles, the microcomputer 1 executes control to increase the gain. That is, when increasing the gain, the microcomputer 1 checks the state of the amplifier IC 2 a plurality of times and increases the gain of the amplifier IC 2. In this way, even when the temperature characteristics are not stable, the microcomputer 1 can stably and reliably execute the control when increasing the gain. On the other hand, as described above, when the microcomputer 1 detects that the detected temperature exceeds the reference temperature (the first temperature) even once, the microcomputer 1 decreases the gain. That is, the microcomputer 1 quickly decreases the gain in response to an increase in the detected temperature in the amplifier IC 2, and increases the gain with stable control in response to a decrease in the detected temperature in the amplifier IC 2. The microcomputer 1 implements quick protection of the amplifier IC 2 and stable control of the gain by selectively using the number of times of monitoring differently in the temperature rising situation and the temperature falling situation.

Further, the microcomputer 1 can control the amplifier IC 2 by using different values as the gain decrease amount ΔG1 and the gain increase amount ΔG2. In this way, the microcomputer 1 implements quick protection of the amplifier IC 2 and stable control of the gain by selectively using the change amount of the gain in the temperature rising situation and the temperature falling situation.

The microcomputer 1 uses the cycle ΔT1, which is the same monitoring cycle, for the control of the gain decrease and the control of the gain increase. When increasing the gain, the microcomputer 1 can freely vary the period ΔT2=N*ΔT1 according to the count number N of the cycles. That is, the microcomputer 1 can flexibly set the change amount of gain in consideration of the gain decrease and the gain increase. Further, the microcomputer 1 can flexibly control the amplifier IC 2 with a desirable value of N in accordance with thermal characteristics of the amplifier IC 2 itself and characteristics of heat radiation components such as a heat radiation plate and a heat sink provided in the amplifier IC 2. That is, the microcomputer 1 implements a quick gain decrease when the temperature of the amplifier IC 2 increases and a stable gain increase when the temperature of the amplifier IC 2 decreases. That is, the microcomputer 1 according to the present embodiment can freely vary the gain decrease due to the decrease amount ΔG1 and the cycle ΔT1 and the gain increase due to the increase amount ΔG2 and the period ΔT2 according to specifications of a product or the like.

### Second Embodiment

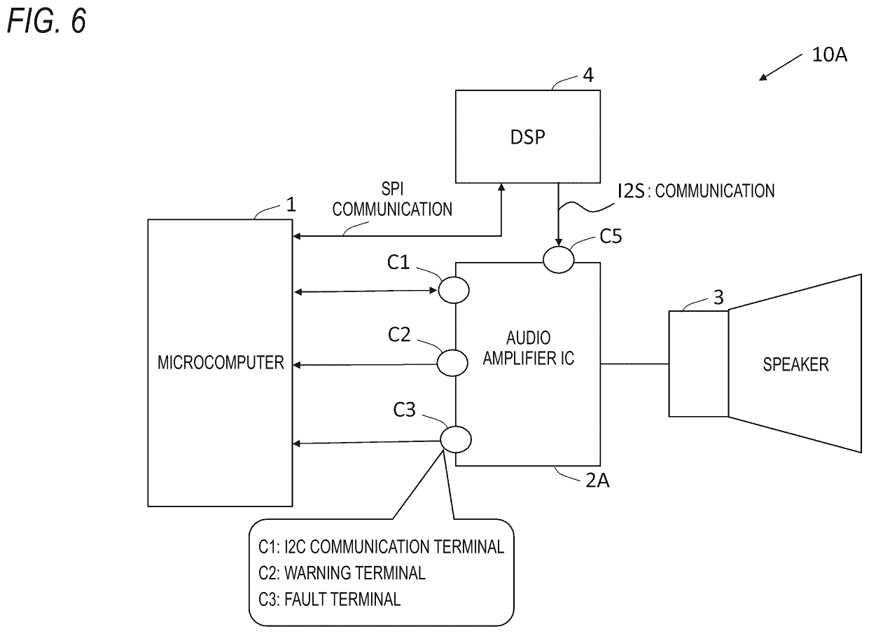

A control system 10A according to a second embodiment will be described with reference to FIG. 6. The first embodiment exemplifies the control system 10 including the microcomputer 1 that determines the state of the amplifier IC 2 from the alarm signal, the fault signal, or the like and controls the gain of the amplifier IC 2. In the first embodiment, the amplifier IC 2 has a function (for example, a register) of receiving gain settings. However, processes of the control system 10 according to the first embodiment can be executed on a device having no function of receiving gain settings.

FIG. 6 shows a configuration of the control system 10A according to the second embodiment. The control system 10A includes the microcomputer 1, an amplifier IC 2A, the speaker 3, and a digital signal processor (DSP) 4.

The DSP 4 can execute SPI communication with the microcomputer 1, and can execute inter-IC sound (I2S) communication with the amplifier IC 2A. The communication between the DSP 4 and the microcomputer 1 is not limited to the SPI communication. The DSP 4 may execute I2C communication with the microcomputer 1.

The DSP 4 decodes, for example, encoded and compressed music data, and inputs, for example, digital audio data in a pulse code modulation (PCM) format to the amplifier IC 2A from a terminal C5 of I2S. An input source of the encoded and compressed music data input to the DSP 4 is not limited. The DSP 4 may read music data via a communication interface connected to a communication network, for example. The DSP 4 may read music data from a DVD, a Blu-ray disc, a hard disk drive, or the like via an input and output interface.

The amplifier IC 2A includes a digital-to-analog (D/A) converter that converts digital audio data into analog data, and an amplifier having a fixed gain. That is, the amplifier IC 2A does not have a function of receiving gain settings. With this configuration, the DSP 4 adjusts an amplitude of the analog audio signal output from the amplifier IC 2A to the speaker 3 by adjusting the number of bits of the digital audio data input to the amplifier IC 2A.

Similar to the first embodiment, the microcomputer 1 reads values of various registers of the amplifier IC 2A through the terminal C1 by I2C communication or the like. The microcomputer 1 may set values, for example, commands or control parameters, in various registers of the amplifier IC 2A through the terminal C1 by I2C communication or the like. That is, the amplifier IC 2A may include a register that can be set from outside for I2C communication or the like. The register for gain settings may not be provided in the amplifier IC 2A.

Similar to the first embodiment, the microcomputer 1 detects an alarm signal from the amplifier IC 2A at the terminal C2. Similar to the first embodiment, the microcomputer 1 detects a fault signal from the amplifier IC 2A at the terminal C3. In the present embodiment, the microcomputer 1 instructs the DSP 4 to increase or decrease the gain by SPI communication instead of instructing the amplifier IC 2A to increase or decrease the gain. That is, similar to the warning monitoring process of FIG. 4 according to the first embodiment, upon detecting the alarm signal from the amplifier IC 2A, the microcomputer 1 may calculate the gain to be set in the amplifier IC 2A and instruct the DSP 4 of the calculated gain.

The DSP 4 may adjust the number of bits of the digital audio data according to the instruction of the gain from the microcomputer 1 and input the digital audio data to the amplifier IC 2A. With such a process, even when the amplifier IC 2A has no gain adjustment function, the microcomputer 1 can adjust the amplitude of the drive signal to the speaker 3 output from the amplifier IC 2A by adjusting the number of bits of the digital audio data in the DSP 4.

Similar to the process of the microcomputer 1 according to the first embodiment, the microcomputer 1 and the DSP 4 make a temporal change of the gain larger when decreasing the gain than when increasing the gain. Accordingly, when the temperature of the amplifier IC 2A is equal to or higher than the reference temperature (the first temperature) and the alarm signal is on, the microcomputer 1 can execute control to quickly lower the temperature of the amplifier IC 2A. In this case, it can also be said that the microcomputer 1 or the like can implement stable control by making the temporal change of the gain smaller when increasing the gain than when decreasing the gain. Further, upon detecting that the detected temperature of the amplifier IC 2A is below the reference temperature (the first temperature) in a plurality of consecutive monitoring cycles (alarm signal off), the microcomputer 1 or the like may execute control to increase the gain. In this way, even when temperature characteristics are not stable, the microcomputer 1 or the like can stably execute the control when increasing the gain. As described above, the DSP 4 and the amplifier IC 2A according to the present embodiment can also be referred to as an example of a control target whose gain can be adjusted when outputting an audio output signal which is an electric signal.

### Third Embodiment

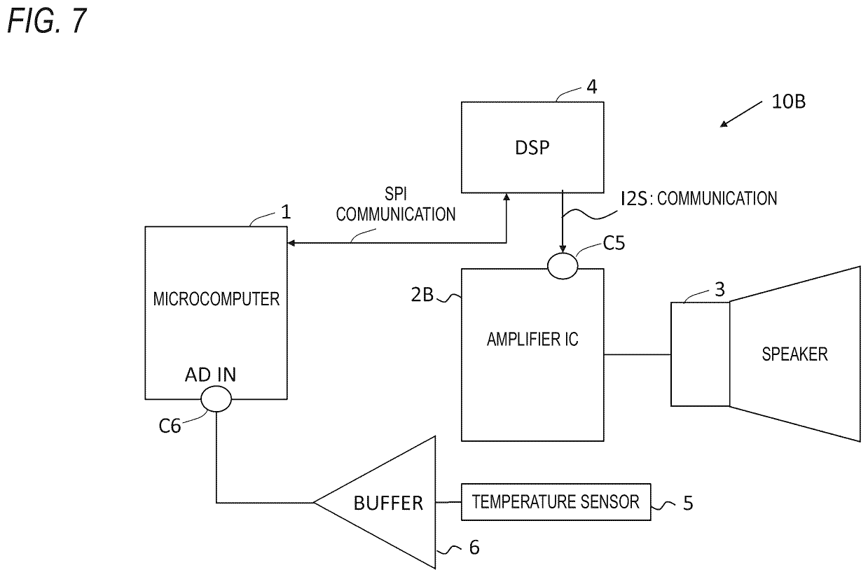

A control system 10B according to a third embodiment will be described with reference to FIG. 7. The first embodiment exemplifies the control system 10 including the microcomputer 1 that determines the state of the amplifier IC 2 from the alarm signal, the fault signal, or the like and controls the gain of the amplifier IC 2. The second embodiment exemplifies the control system 10A including the amplifier IC 2A that has no function of receiving gain settings. That is, the second embodiment exemplifies the control system 10A in which the microcomputer 1 determines the state of the amplifier IC 2A and the DSP 4 and the amplifier IC 2A adjusts an output amplitude of a drive signal to the speaker 3. The present embodiment exemplifies the control system 10B including an amplifier IC 2B that has no temperature detection function or communication function with the microcomputer 1.

FIG. 7 shows a configuration of the control system 10B according to the third embodiment. In the present embodiment, the control system 10B includes the microcomputer 1, the amplifier IC 2B, the speaker 3, and the DSP 4. In the present embodiment, configurations and operations of the microcomputer 1, the speaker 3, and the DSP 4 are the same as those of the second embodiment.

That is, the microcomputer 1 is connected to the DSP 4 by, for example, SPI communication or so on. Further, the DSP 4 can adjust the number of bits of digital audio data by the I2S communication and input the digital audio data to the amplifier IC 2B.

The amplifier IC 2B performs D/A conversion on the digital audio data and then amplifies the digital audio data with a fixed gain to drive the speaker 3. However, unlike the amplifier IC 2 according to the first embodiment and the amplifier IC 2A according to the second embodiment, the amplifier IC 2B does not include a temperature sensor therein. The amplifier IC 2B has no communication function of outputting an alarm signal and a fault signal or notifying the microcomputer 1 or the like of the alarm signal and the fault signal.

In the present embodiment, a temperature sensor 5, which measures a temperature of the amplifier IC 2B, and a buffer circuit (BUFFER) 6, which converts temperature data detected by the temperature sensor 5 into digital data and inputs the digital data to a digital (AD IN) terminal C6 of the microcomputer 1, are provided.

In the present embodiment, the microcomputer 1 detects, instead of the amplifier IC 2B, a temperature state of the amplifier IC 2B. That is, the microcomputer 1 monitors the temperature measured by the temperature sensor 5. When the temperature of the amplifier IC 2B rises and reaches the reference temperature (the first temperature) while the amplifier IC 2B is amplifying an audio signal, the microcomputer 1 instructs the DSP 4 to decrease the gain of the amplifier IC 2B. Upon consecutively detecting N times that the temperature of the amplifier IC 2B is kept below the reference temperature (the first temperature), the microcomputer 1 instructs the DSP 4 to increase the gain of the amplifier IC 2B. Similar to the second embodiment, the DSP 4 adjusts the number of bits of the digital audio data and inputs the digital audio data to the amplifier IC 2B, thereby adjusting the gain.

Further, when the temperature of the amplifier IC 2B reaches the limit temperature (the second temperature) while the amplifier IC 2B is amplifying the audio signal, the microcomputer 1 stops an input of the digital audio data to the amplifier IC 2B by the DSP 4 and executes an abnormality process.

Similar to the first embodiment and the second embodiment, the microcomputer 1 or the like makes a temporal change of the gain larger when decreasing the gain than when increasing the gain. Accordingly, when the temperature of the amplifier IC 2B is equal to or higher than the reference temperature (the first temperature), the microcomputer 1 or the like can execute control to quickly lower the temperature of the amplifier IC 2B. In this case, it can also be said that the microcomputer 1 or the like can implement stable control by making the temporal change of the gain smaller when increasing the gain than when decreasing the gain. Further, upon detecting that the detected temperature of the amplifier IC 2B is below the reference temperature (the first temperature) in a plurality of consecutive monitoring cycles, the microcomputer 1 or the like may execute control to increase the gain. In this way, even when temperature characteristics are not stable, the microcomputer 1 can stably execute the control when increasing the gain. According to the configurations described above, the microcomputer 1 and the DSP 4 can implement quick protection of the amplifier IC 2B and stable control of the gain as in the first and second embodiments.

### Other Embodiments

The first to third embodiments exemplify processes of adjusting outputs of the amplifier IC 2 to the amplifier IC 2B in the control systems 10 to 10B which are audio systems for driving the speaker 3. However, the processes of the control systems 10 to 10B and the like are not limited to the audio systems. That is, similar to the amplifier IC 2 to the amplifier IC 2B, the processes of the control systems 10 to 10B can be applied to all systems including a device whose temperature changes according to an output signal. For example, the processes of the control systems 10 to 10B may be applied to an amplifier circuit provided in a control circuit of an air conditioner. The processes of the control systems 10 to 10B may be applied to an amplifier circuit provided in a driver circuit that controls luminance of an image output device. Further, the processes of the control systems 10 to 10B may be applied to a transmission circuit or an amplifier circuit that controls transmission power of a communication device.

In a device including such an amplifier circuit or the like, the microcomputer 1 or the like makes a temporal change of a gain larger when decreasing the gain than when increasing the gain. Accordingly, when a temperature of the device such as the amplifier IC 2 is equal to or higher than the reference temperature (the first temperature), the microcomputer 1 can execute quick control to lower the temperature of the amplifier IC 2. In this case, it can also be said that the microcomputer 1 or the like can implement stable control by making the temporal change of the gain smaller when increasing the gain than when decreasing the gain. Further, upon detecting that the detected temperature of the amplifier IC 2 or the like is below the reference temperature (the first temperature) in a plurality of consecutive monitoring cycles, the microcomputer 1 or the like may execute control to increase the gain. In this way, even when temperature characteristics are not stable, the microcomputer 1 or the like can stably execute the control when increasing the gain. The microcomputer 1 or the like can implement quick protection of the amplifier IC 2 or the like and stable control of the gain by selectively using the number of times of monitoring differently in the temperature rising situation and the temperature falling situation.

### Computer-Readable Recording Medium

A program that causes a computer or another machine or device (hereinafter, referred to as the computer or the like) to implement one of the above functions can be recorded on a non-transitory computer-readable recording medium. The function can be provided by causing the computer or the like to read and execute the program on the recording medium.

Here, the computer-readable recording medium refers to a recording medium that stores information such as data and programs by an electrical, magnetic, optical, mechanical, or chemical operation and can be read by a computer or the like. Among such recording media, a medium that is removable from the computer or the like includes, for example, a memory card such as a flexible disc, a magneto-optical disc, a compact disc read only memory (CD-ROM), a CD read/write (CD-R/W), a digital versatile disc (DVD), a Blu-ray disc, and a flash memory. A recording medium fixed in a computer or the like includes a hard disk, a ROM, or the like. A solid state drive (SSD) may be used as a recording medium movable from a computer or the like or a recording medium fixed to a computer or the like.

### Others

The present embodiment includes the following aspects (hereinafter referred to as appendixes).

### Appendix 1

A control device comprising circuitry configured to:
execute control to decrease a gain when a detected temperature of a control target is equal to or higher than a first temperature, and then increase the gain when the detected temperature becomes lower than the first temperature, the gain when outputting an electric signal being adjustable; and
cause a temporal change of the gain to be smaller when increasing the gain than when decreasing the gain.

### Appendix 2

The control device according to Appendix 1, in which
the circuitry is configured to stop the output of the control target when the detected temperature reaches a second temperature higher than the first temperature.

### Appendix 3

The control device according to Appendix 1 or 2, in which
the circuitry is configured to output a warning when the detected temperature of the control target is equal to or higher than the first temperature.

### Appendix 4

The control device according to any one of Appendixes 1 to 3, in which
the circuitry is configured to detect a state of the control target in each monitoring cycle for monitoring the control target, and control to increase the gain when the detected temperature becomes lower than the first temperature in a plurality of consecutive monitoring cycles.

### Appendix 5

A control method performed by a computer, including:
executing control to decrease a gain when a detected temperature of a control target is equal to or higher than a first temperature, and then increasing the gain when the detected temperature is lower than the first temperature, the gain when outputting an electric signal being adjustable; and
causing a temporal change of the gain to be smaller when increasing the gain than when decreasing the gain.

### Appendix 6

The control method according to Appendix 5, further including
outputting a warning when the detected temperature of the control target is equal to or higher than the first temperature.

### Appendix 7

The control method according to Appendix 5 or 6, further including
outputting a warning when the detected temperature of the control target is equal to or higher than the first temperature.

### Appendix 8

The control method according to any one of Appendixes 5 to 7, further including
detecting a state of the control target in each monitoring cycle for monitoring the control target, and controlling to increase the gain upon detecting that the detected temperature is lower than the first temperature in a plurality of consecutive monitoring cycles.

1. A control device comprising circuitry configured to:
execute control to decrease a gain when a detected temperature of a control target is equal to or higher than a first temperature, and then increase the gain when the detected temperature becomes lower than the first temperature, the gain when outputting an electric signal being adjustable; and
cause a temporal change of the gain to be smaller when increasing the gain than when decreasing the gain.

2. The control device according to claim 1, wherein
the circuitry is configured to stop the output of the control target when the detected temperature reaches a second temperature higher than the first temperature.

3. The control device according to claim 1, wherein
the circuitry is configured to output a warning when the detected temperature of the control target is equal to or higher than the first temperature.

4. The control device according to claim 1, wherein
the circuitry is configured to detect a state of the control target in each monitoring cycle for monitoring the control target, and control to increase the gain when the detected temperature becomes lower than the first temperature in a plurality of consecutive monitoring cycles.

5. A control method performed by a computer, comprising:
executing control to decrease a gain when a detected temperature of a control target is equal to or higher than a first temperature, and then increasing the gain when the detected temperature is lower than the first temperature, the gain when outputting an electric signal being adjustable; and
causing a temporal change of the gain to be smaller when increasing the gain than when decreasing the gain.

6. The control method according to claim 5, further comprising
stopping the output of the control target when the detected temperature reaches a second temperature higher than the first temperature.

7. The control method according to claim 5, further comprising
outputting a warning when the detected temperature of the control target is equal to or higher than the first temperature.

8. The control method according to claim 5, further comprising
detecting a state of the control target in each monitoring cycle for monitoring the control target, and controlling to increase the gain upon detecting that the detected temperature is lower than the first temperature in a plurality of consecutive monitoring cycles.
